(19) United States
(12) Patent Application Publication
(10) Pub. No.: US 2026/0221713 A1
(43) Pub. Date: Jul. 30, 2026

(54) LIGHT EMITTING DEVICE

(71) Applicant: SONY SEMICONDUCTOR SOLUTIONS CORPORATION, KANAGAWA (JP)

(72) Inventor: SATOSHI IMAIZUMI, KUMAMOTO (JP)

(21) Appl. No.: 19/152,277

(22) PCT Filed: Jan. 23, 2024
(86) PCT No.: PCT/JP2024/001745

§ 371 Date: Jul. 30, 2025

(30) Foreign Application Priority Data
Feb. 13, 2023 (JP) 2023-019903

(51) Int. Cl. H01S 5/02; H01S 5/042; H01S 5/183

(52) U.S. Cl. CPC H01S 5/0207; H01S 5/0421; H01S 5/18361

(57) ABSTRACT

For example, a light emitting device having a structure capable of performing arbitrary lateral mode control is provided. A light emitting device includes: a substrate having a first main surface and a second main surface on an opposite side thereof to the first main surface; and a light emitting unit formed on the first main surface of the substrate, in which the light emitting unit includes a first structure including a first multilayer film reflector, a second structure including a second multilayer film reflector, and an active layer disposed between the first structure and the second structure, a groove connected to the second main surface of the substrate is formed in a facing region facing at least a part of a light emitting region of the active layer, and a metal portion is formed inside the groove.

### TECHNICAL FIELD

The present technology relates to, for example, a light emitting device including a surface emitting semiconductor laser.

### BACKGROUND ART

A vertical cavity surface emitting laser (Hereinafter, also referred to as VCSEL as appropriate) has been proposed as one of light sources used in electronic equipment such as a distance measuring device, a digital copier, a printer, and a communication device. For example, the following PTL 1 discloses a VCSEL suitable for applications requiring a perfect circular beam profile.

### CITATION LIST

### Patent Literature

### [PTL 1]

JP 2010-050412 A

### SUMMARY

### Technical Problem

In general, the lateral mode characteristic of the VCSEL greatly changes depending on the shape and size of the light emitting region. Depending on the application of the VCSEL, it may be required that the optical output of the basic lateral mode be large as the lateral mode characteristic, or it may be required that the optical output of the higher order lateral mode be large. Therefore, a structure of the VCSEL capable of lateral mode control that can meet these requirements is desired.

An object of the present technology is to provide a light emitting device having a structure capable of performing arbitrary lateral mode control, for example.

### Solution to Problem

The present technology is, for example, a light emitting device including:
a substrate having a first main surface and a second main surface on an opposite side thereof to the first main surface; and
a light emitting unit formed on the first main surface of the substrate, in which
the light emitting unit includes:
a first structure that includes a first multilayer film reflector;
a second structure that includes a second multilayer film reflector; and
an active layer that is disposed between the first structure and the second structure,
a groove connected to the second main surface of the substrate is formed in a facing region facing at least a part of a light emitting region of the active layer, and
a metal portion is formed inside the groove.

### BRIEF DESCRIPTION OF DRAWINGS

FIG. 1 is a diagram that is referred to when a problem to be considered in the present technology is described.

FIG. 2 is a diagram that is referred to when a problem to be considered in the present technology is described.

FIG. 3 is a diagram that is referred to when a problem to be considered in the present technology is described.

FIG. 4 is a diagram that is referred to when a problem to be considered in the present technology is described.

FIG. 5 is a diagram that is referred to when a problem to be considered in the present technology is described.

FIG. 6 is a diagram that is referred to when a problem to be considered in the present technology is described.

FIG. 7 is a cross-sectional view for explaining an exemplary structure of a VCSEL according to a first embodiment.

FIG. 8 is a plan view for explaining an exemplary structure of a VCSEL according to the first embodiment.

FIG. 9 is a diagram illustrating an example of lateral mode characteristics of laser light emitted from the VCSEL according to the first embodiment.

FIG. 10 is a diagram for explaining a heat dissipation function by the VCSEL according to the first embodiment.

FIG. 11 is a cross-sectional view for explaining an exemplary structure of a VCSEL according to a second embodiment.

FIG. 12 is a cross-sectional view for explaining an exemplary structure of a VCSEL according to the second embodiment.

FIG. 13 is a diagram illustrating an example of lateral mode characteristics of laser light emitted from a VCSEL according to the second embodiment.

FIG. 14 is a diagram for explaining a heat dissipation function by the VCSEL according to the second embodiment.

FIG. 15 is a plan view for explaining an exemplary structure of a VCSEL according to a third embodiment.

FIG. 16 is a cross-sectional view for explaining an exemplary structure of a VCSEL according to the third embodiment.

FIG. 17 is a cross-sectional view for explaining an exemplary structure of a VCSEL according to the third embodiment.

FIG. 18 is a diagram for explaining an example of lateral mode characteristics of laser light emitted from a VCSEL according to a third embodiment.

FIG. 19 is a diagram for explaining an example of lateral mode characteristics of laser light emitted from a VCSEL according to the third embodiment.

FIG. 20 is a diagram for explaining a heat dissipation function by the VCSEL according to the third embodiment.

FIG. 21 is a diagram for explaining a heat dissipation function by the VCSEL according to the third embodiment.

FIG. 22 is a diagram for explaining a modification example.

FIG. 23 is a diagram for explaining a modification example.

FIG. 24 is a diagram for explaining a modification example.

FIG. 25 is a diagram for explaining a modification example.

FIG. 26 is a block diagram illustrating a schematic configuration example of a vehicle control system.

FIG. 27 is an explanatory diagram illustrating an example of installation positions of a vehicle external information detection unit and an imaging unit.

### DESCRIPTION OF EMBODIMENTS

Hereinafter, embodiments and the like of the present technology will be described with reference to the drawings. Here, the descriptions will be given in the following order.
<Problems to Be Considered in Present Technology>
<First Embodiment>
<Second Embodiment>
<Third Embodiment>
<Modification>
<Application Example>

The embodiments described below are preferred specific examples of the present technology, and the contents of the present technology are not limited to the embodiments.

Note that sizes, positional relationships, and the like of members illustrated in the drawings may be exaggerated for clarity of description, and only a part of reference numerals may be illustrated or a part of the illustration may be simplified in order to prevent the illustration from being complicated.

Furthermore, in the following description, the same names and reference numerals indicate the same or similar members, and redundant description will be appropriately omitted.

### PROBLEMS TO BE CONSIDERED IN PRESENT TECHNOLOGY

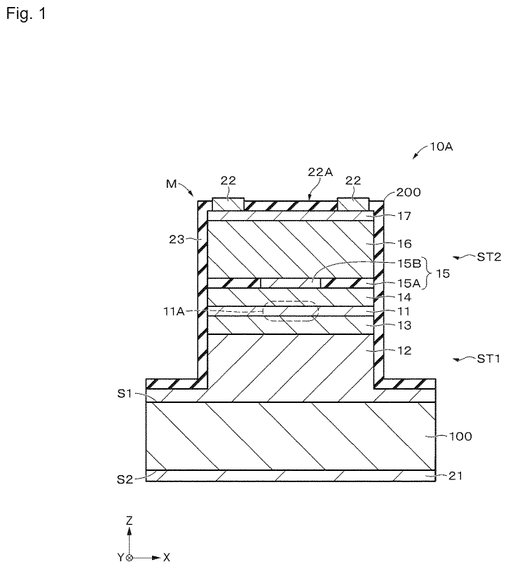

A light emitting device according to the present technology includes one or a plurality of light emitting units. Hereinafter, a VCSEL will be described as an example of the light emitting unit. Before describing a light emitting device according to an embodiment, problems to be considered in the present technology will be described with reference to FIGS. 1 to 5 in order to facilitate understanding of the present technology.

### Exemplary Structure of VCSEL

FIG. 1 is a cross-sectional view for explaining an exemplary structure of a general VCSEL (VCSEL 10A). The VCSEL 10A includes a light emitting unit 200 formed on a first main surface S1 side which is one main surface of a substrate 100. The light emitting unit 200 schematically includes a first structure ST1, a second structure ST2, and an active layer 11 disposed between the first structure ST1 and the second structure ST2. The first structure ST1, the active layer 11, and the second structure ST2 are stacked in this order from the first main surface S1 side of the substrate 100. A resonator is configured by the first structure ST1, the second structure ST2, and the active layer 11.

Specifically, the light emitting unit 200 is configured by stacking a first multilayer film reflector 12, a first spacer layer 13, an active layer 11, a second spacer layer 14, a current confinement layer 15, a second multilayer film reflector 16, and a contact layer 17 in this order from the first main surface S1 side of the substrate 100. The light emitting unit 200 includes a first electrode 21, a second electrode 22, and a protective layer 23. In this example, the first structure ST1 includes, for example, a first multilayer film reflector 12 and a first spacer layer 13. The second structure ST2 includes, for example, a second spacer layer 14, a current confinement layer 15, a second multilayer film reflector 16, and a contact layer 17.

For example, the first structure ST1, the second structure ST2, and the active layer 11 constitute a mesa portion M having a top portion in the second structure ST2. The mesa portion M has, for example, a substantially cylindrical shape, but may have other shapes such as a substantially elliptical columnar shape, a polygonal columnar shape, a truncated cone shape, an elliptical frustum shape, and a polygonal frustum shape. The height direction of the mesa portion M substantially coincides with the stacking direction (Z direction in FIG. 1) of the VCSEL 10A. The diameter of the mesa portion M is, for example, 1 μm to 500 μm. The VCSEL 10A according to the present example is, for example, a VCSEL of back-emitting type.

### Substrate

The substrate 100 is, for example, an n-type GaAs substrate, and the GaAs substrate is preferably, for example, a (100) plane substrate, but may be a special substrate such as an (n11) plane substrate (n is an integer).

### First Structure

The first structure ST1 includes the first multilayer film reflector 12 formed on the first main surface S1 of the substrate 100. More specifically, the first structure ST1 includes the first multilayer film reflector 12 and the first spacer layer 13 stacked on the first multilayer film reflector 12.

The first multilayer film reflector 12 is, for example, a semiconductor multilayer film reflector. The multilayer film reflector is also referred to as a distributed Bragg reflector. More specifically, the first multilayer film reflector 12 is, for example, a semiconductor multilayer film reflector of a first conductivity type (for example, n-type), and has a structure in which a plurality of types (for example, two types) of semiconductor layers having different refractive indexes are alternately stacked with an optical thickness of ¼ wavelength of the oscillation wavelength. Each refractive index layer of the first multilayer film reflector 12 is made of a first conductivity type (for example, n-type) AlGaAs-based compound semiconductor.

The first spacer layer 13 is made of, for example, n-type Alx1Ga1-x1As (0<x1<1).

### Second Structure

The second spacer layer 14 is made of, for example, Alx2Ga1-x2As (0<x2<1).

The current confinement layer 15 has a current confinement region 15A in an outer edge region thereof and a current injection region 15B in a central region thereof. The current injection region 15B is made of, for example, p-type Alx3Ga1-x3As (0<x3≤1). The current confinement region 15A is configured to contain Al203 (aluminum oxide), and is obtained by oxidizing high-concentration Al contained in the Alx3Ga1-x3As layer from the side surface side of the mesa portion M. That is, the current confinement layer 15 has a function of constricting the current.

Note that, in this example, the current confinement region 15A is formed by, for example, oxidizing and insulating Al, but the method is not limited thereto as long as current confinement can be performed. For example, the current confinement region 15A may be formed by being insulated by deactivation by ion implantation into the outer peripheral portion of the mesa portion M. In addition, the current confinement region 15A may be formed by a QWI or an embedded TJ that confines carriers by providing a band gap energy difference between the aperture diameter portion and the outside thereof by Ga hole diffusion.

The second multilayer film reflector 16 is, for example, a semiconductor multilayer film reflector. A semiconductor multilayer film reflector which is a type of multilayer film reflector (distributed Bragg reflector) has low light absorption, high reflectance, and conductivity. More specifically, the second multilayer film reflector 16 is, for example, a semiconductor multilayer film reflector of a second conductivity type (for example, p-type), and has a structure in which a plurality of types (for example, two types) of semiconductor layers having different refractive indexes are alternately stacked with an optical thickness of ¼ wavelength of the oscillation wavelength. The reflectance of the second multilayer film reflector 16 is set slightly higher than that of the first multilayer film reflector 12.

The contact layer 17 is made of p-type GaAs, for example.

### Active Layer

As an example, the active layer 11 has a quantum well structure including a barrier layer made of an AlGaAs-based compound semiconductor and a quantum well layer. This quantum well structure may be a single quantum well structure (QW structure) or a multiple quantum well structure (MQW structure). In the active layer 11, a region corresponding to the current injection region 15B (current passage portion) of the current confinement layer 15 described above is a light emitting region 11A. Note that the active layer 11 may have a plurality of QW structures or a plurality of MQW structures stacked via tunnel junctions.

The center region (light emission center region) of the light emitting region 11A is a region where the basic lateral mode oscillation mainly occurs, and the outer edge region surrounding the light emission center region in the light emitting region 11A is a region where the higher order lateral mode oscillation mainly occurs. For example, Y-polarized light is generated by basic lateral mode oscillation, and X-polarized light is generated by higher order lateral mode oscillation.

It is desirable that the active layer 11, the first spacer layer 13, and the second spacer layer 14 described above do not contain impurities, but may contain p-type or n-type impurities. Examples of the p-type impurity include zinc (Zn), magnesium (Mg), and beryllium (Be).

### First Electrode and Second Electrode

The first electrode 21 (lower electrode) is formed on a second main surface S2 (main surface opposite to the first main surface S1) of the substrate 100. The first electrode 21 is, for example, a cathode electrode. The first electrode 21 is formed over the entire second main surface S2 of the substrate 100. That is, in the present example, the first electrode 21 (cathode electrode in the present example) is a common electrode for the plurality of light emitting units 200.

The first electrode 21 has a structure in which, for example, an alloy of gold (Au) and germanium (Ge), nickel (Ni), and gold (Au) are stacked in order from the second main surface S2 side of the substrate 100.

On the upper surface of the contact layer 17, an annular second electrode 22 (upper electrode) having an opening (light exit port 22A) in a facing region to at least the current injection region 15B is formed. The second electrode 22 is, for example, an anode electrode.

The second electrode 22 has, for example, a structure in which titanium (Ti), platinum (Pt), and gold (Au) are stacked in this order. In this example, the cathode electrode is the common electrode, and the anode electrode is provided for each light emitting unit 200. However, depending on the structure of the light emitting unit 200, the anode electrode may be the common electrode, and the cathode electrodes may be separately provided.

In the VCSEL 10A according to this example, the protective layer 23 is formed on the outer edge portion of the upper surface of the mesa portion M and the surface of the contact layer 17 other than the mesa portion M. The protective layer 23 is formed of, for example, an insulating material such as an oxide or a nitride, and is formed so as to cover the surface of the light emitting unit 200 excluding the second electrode 22.

### Operation Example of VCSEL

Next, an operation example of the VCSEL 10A will be described. For example, the current supplied from the anode side of the laser driver and flowing in from the second electrode 22 (anode electrode) passes through the second multilayer film reflector 16, is narrowed in the current confinement region 15A, and is injected into the active layer 11. At this time, the active layer 11 emits light, and the light is amplified by the active layer 11 between the first multilayer film reflector 12 and the second multilayer film reflector 16 and reciprocates while being confined in the current confinement region 15A, and is emitted as laser light from the back surface of the substrate 100 when the oscillation conditions are satisfied. The current that has passed through the active layer 11 reaches the first electrode 21 (cathode electrode) via the first spacer layer 13 and the first multilayer film reflector 12, and flows out from the first electrode 21 to, for example, the cathode side of the laser driver.

### Another Exemplary Structure of VCSEL

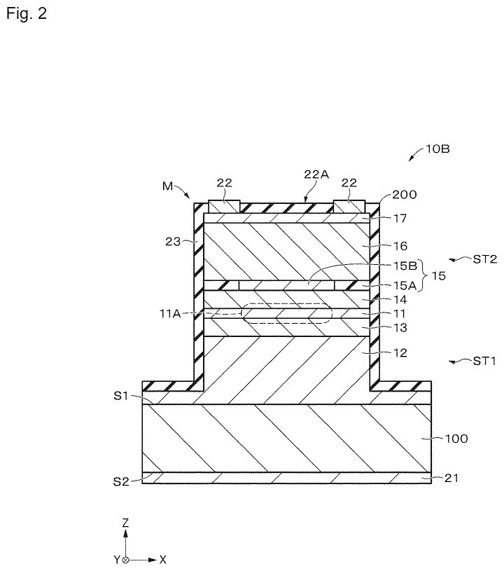

FIG. 2 is a cross-sectional view for explaining an exemplary structure of another VCSEL (VCSEL 10B). The structure of the VCSEL 10B is basically the same as that of the VCSEL 10A. The structural difference is that in the VCSEL 10B, the region of the current confinement region 15A is smaller than that of the VCSEL 10A, and as a result, the region of the current injection region 15B is larger than that of the VCSEL 10A.

By the way, since the lateral mode characteristic (spatial distribution of light intensity) of the VCSEL depends on the diameter of the current injection region 15B in the current confinement layer 15, there is a method of adjusting the diameter of the current injection region 15B to control the lateral mode characteristic.

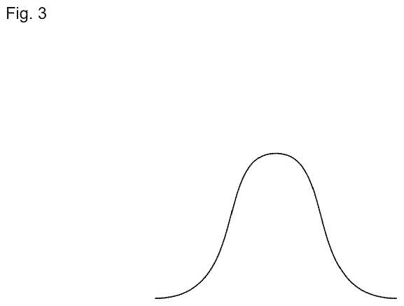

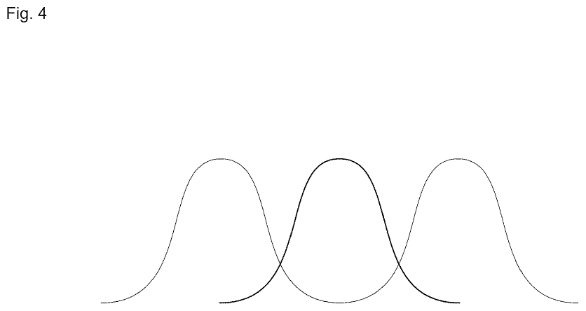

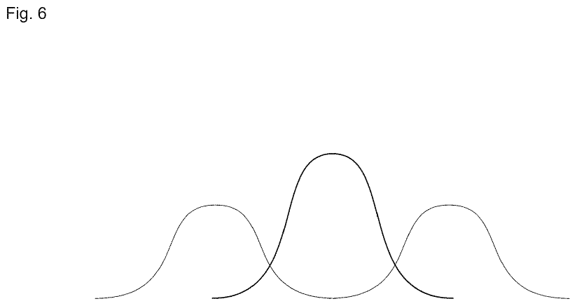

For example, as in the VCSEL 10A illustrated in FIG. 1, if the diameter of the current injection region 15B is reduced, the lateral mode characteristic becomes a basic (single) lateral mode in which the light intensity (the same applies to vertical directions in FIGS. 4, 6, 9, 13, 18, and 19) near the center of the light emitting region 11A increases, as schematically illustrated in FIG. 3. On the other hand, when the diameter of the current injection region 15B is increased as in the VCSEL 10B illustrated in FIG. 2, the lateral mode characteristic is a characteristic in which a higher order lateral mode oscillates also in the vicinity of the outer periphery of the light emitting region 11A as schematically illustrated in FIG. 4. In FIGS. 3 and 4, the lateral mode characteristic of the basic lateral mode is indicated by a slightly thick line, and the lateral mode characteristic of the higher order lateral mode is indicated by a thin line. The same applies to FIGS. 6, 9, 13, 18, and 19.

However, in the former case, there is a problem that the optical output decreases and the voltage/electric resistance increases. On the other hand, in the latter case, there is a problem that it is difficult to control only a specific lateral mode such as increasing the light intensity of only a higher order lateral mode.

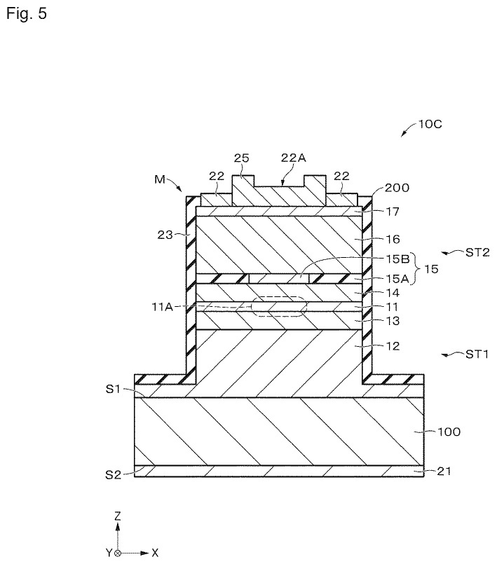

In addition, as illustrated in FIG. 5, a structure of a VCSEL (VCSEL 10C) in which a lateral mode control layer 25 is formed in the vicinity of a light exit port 22A is also proposed. The lateral mode control layer 25 has a structure capable of locally imparting a reflectance difference or absorbing light in the vicinity of the light exit port 22A. According to the structure of the VCSEL 10C, the controllability of the lateral mode can be obtained. For example, as illustrated in FIG. 6, the light intensity of the light of the higher order lateral mode can be made smaller than the light intensity of the light of the basic lateral mode.

However, there is a possibility that the light intensity of the emitted laser light decreases as the light emitted to the outside decreases due to an increase in reflectance in the lateral mode control layer 25 on the light emission side. In addition, there is a possibility of an optical loss due to an increase in overall light absorption in the lateral mode control layer 53.

That is, a light emitting device having a structure capable of performing arbitrary lateral mode control while suppressing a decrease in light intensity and light absorption on an emission side of laser light as much as possible is desired. Based on the above points, the present disclosure will be specifically described with reference to the embodiments.

### FIRST EMBODIMENT

### Exemplary Structure of VCSEL

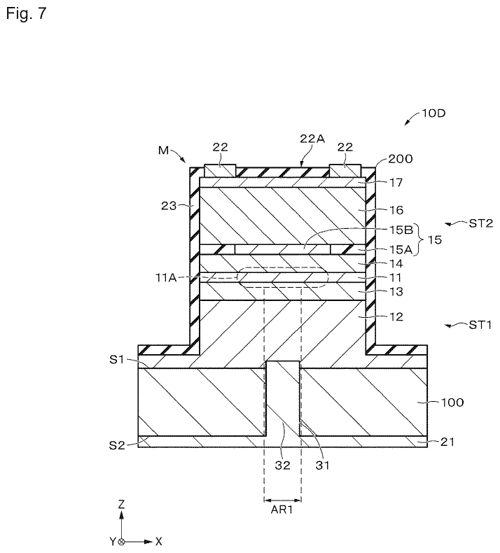

In a first embodiment, any lateral mode that enhances light intensity is an example of a basic lateral mode. FIG. 7 is a cross-sectional view illustrating a cross section of a VCSEL (VCSEL 10D) according to the first embodiment. The VCSEL 10D has a groove 31 connected to the second main surface S2 of the substrate 100 in a facing region facing at least a part of the light emitting region 11A of the active layer 11.

The groove 31 is formed, for example, in a facing region AR1 facing the vicinity of the center (substantially center) of the light emitting region 11A. The groove 31 is formed, for example, by excavating the inside of the substrate 100 from the second main surface S2 of the substrate 100, and excavating from the first main surface S1 of the substrate 100 to about several semiconductor layers of the first multilayer film reflector 12. That is, the depth of the groove 31 (the length in the Z direction in FIG. 7) is about the sum of the thickness of the substrate 100 and the number of semiconductor layers of the first multilayer film reflector 12.

A metal portion 32 is provided inside the groove 31. In the present embodiment, the metal portion 32 is provided inside the entire groove 31. The metal portion 32 is made of a metal material having a high reflectance with respect to the laser oscillation wavelength of the VCSEL 10D. The metal portion 32 contains, for example, at least one metal element selected from the group consisting of gold (Au), aluminum (Al), copper (Cu), titanium (Ti), platinum (Pt), palladium (Pd), germanium (Ge), zinc (Zn), silver (Ag), and tungsten (W).

In the present embodiment, the metal portion 32 is connected to the first electrode 21 formed on the second main surface S2 of the substrate 100 (integrally formed). The metal portion 32 is made of, for example, the same metal material as that of the first electrode 21. As a result, when the first electrode 21 is formed on the second main surface S2 of the substrate 100, the metal portion 32 can be formed simultaneously.

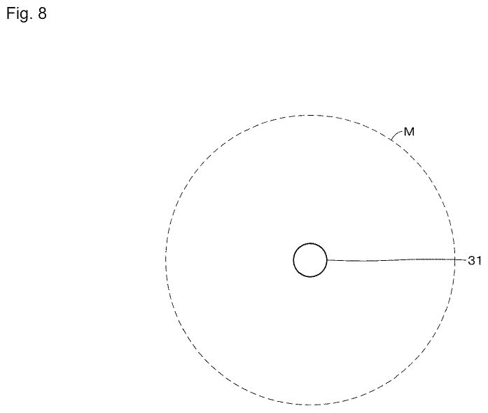

FIG. 8 is a schematic plan view of the VCSEL 10D according to the present embodiment in a plan view. With respect to the mesa portion M having an isotropic shape, the groove 31 is formed in the facing region AR1 facing the vicinity of the center of the light emitting region 11A. In FIG. 8, only the mesa portion M (dotted line) and the groove 31 (solid line) are illustrated in order to prevent the illustration from being complicated.

### Method for Producing VCSEL

Next, an example of a method for manufacturing the VCSEL 10D will be schematically described. First, the substrate 100 made of GaAs is prepared. Next, on the first main surface S1 of the substrate 100, for example, the first multilayer film reflector 12, the first spacer layer 13, the active layer 11, the second spacer layer 14, the current confinement layer 15, the second multilayer film reflector 16, and the contact layer 17 are epitaxially grown in order from the substrate 100 by, for example, a metal organic chemical vapor deposition (MOCVD) method.

When MOCVD is performed, for example, trimethylgallium ((CH3)3Ga) is used as a source gas of gallium, for example, trimethylaluminum ((CH3)3Al) is used as a source gas of aluminum, for example, trimethylindium ((CH3)3In) is used as a source gas of indium, and for example, trimethylarsenic ((CH3)3As) is used as a source gas of As. In addition, for example, monosilane (SiHI4) is used as the source gas of silicon, and, for example, carbon tetrabromide (CBr4) is used as the source gas of carbon.

Subsequently, water vapor oxidation is performed on the easily oxidizable layer formed at the time of crystal growth to form the current confinement region 15A which is a region where oxidation has progressed.

Then, the second electrode 22 is formed. The second electrode 22 is formed so as to be in contact with the contact layer 17. For example, the second electrode 22 may be formed by a film deposition technique called lift-off.

Next, the protective layer 23 as an insulator is formed on the first main surface S1 of the substrate 100, the peripheral surface of the first structure ST1, and the peripheral surface of the second structure ST2 (a portion excluding the second electrode 22). For example, the protective layer 23 can be formed by a method for preparing the desired shape by depositing a protective film over the entire surface and performing etching.

Thereafter, an etching mask using a resist or the like is formed on the second main surface S2 of the substrate 100. Then, by etching, the substrate 100 is excavated from a desired position on the second main surface S2 of the substrate 100, and from the second main surface S2 to about several semiconductor layers of the first multilayer film reflector 12 are excavated. Thus, the groove 31 is formed. Then, a metal material having a high reflectance with respect to the laser oscillation wavelength is deposited by sputtering or plating so as to fill the groove 31 and cover the second main surface S2 of the substrate 100. As a result, the first electrode 21 and the metal portion 32 are formed.

### Operation of VCSEL

Next, an operation example of the VCSEL 10D will be described. For example, the current supplied from the anode side of the laser driver and flowing in from the second electrode 22 (anode electrode) passes through the second multilayer film reflector 16, is narrowed in the current confinement region 15A, and is injected into the active layer 11. At this time, the active layer 11 emits light, and the light is amplified by the active layer 11 between the first multilayer film reflector 12 and the second multilayer film reflector 16 and reciprocates while being confined in the current confinement region 15A, and is emitted as laser light from the back surface of the substrate 100 when the oscillation conditions are satisfied. The current that has passed through the active layer 11 reaches the first electrode 21 (cathode electrode) via the first spacer layer 13 and the first multilayer film reflector 12, and flows out from the first electrode 21 to, for example, the cathode side of the laser driver.

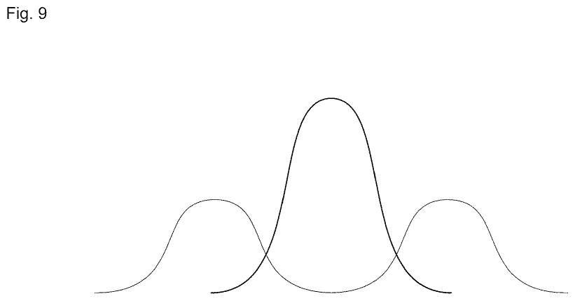

In the present embodiment, the metal portion 32 is formed in the facing region AR1. The metal portion 32 can increase the reflectance of the portion where the metal portion 32 is formed and can facilitate laser oscillation. As a result, the light intensity in the lateral mode corresponding to the portion where the metal portion 32 is formed can be enhanced. Since the facing region AR1 according to the present embodiment is a region facing the vicinity of the center of the light emitting region 11A, the light intensity of the basic lateral mode can be enhanced as schematically illustrated in FIG. 9.

### Effects Obtained in Present Embodiment

According to the VCSEL 10D according to the present embodiment, the following effects can be obtained.

Since the reflectance of the portion where the metal portion 32 is provided can be increased, the light intensity of light in an arbitrary lateral mode, specifically, the basic lateral mode can be enhanced.

Since the metal portion 32 has a reflectance control structure provided on the side opposite to the light exit port 22A, it is possible to suppress a decrease in light intensity caused by an increase in reflectance at the light exit port 22A as much as possible.

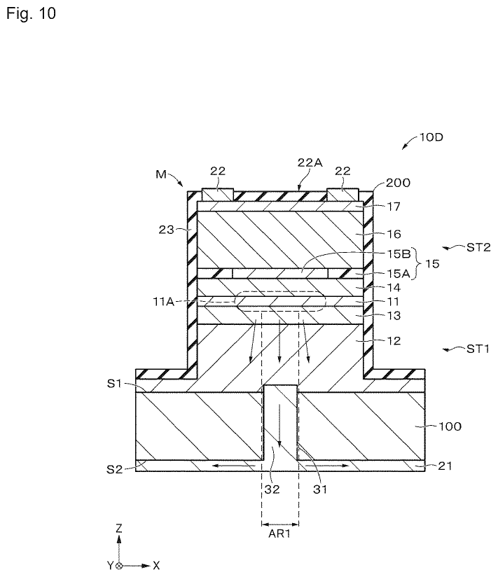

In addition, with the structure in which the metal portion 32 is provided in the facing region AR1 facing the light emitting region 11A and the metal portion 32 is connected (integrated) with the first electrode 21, heat generated in the light emitting region 11A can be effectively dissipated. For example, as schematically indicated by an arrow in FIG. 10, heat generated in the light emitting region 11A is transferred to the metal portion 32. The heat transferred to the metal portion 32 is transferred to the first electrode 21. Since the first electrode 21 is formed over the entire second main surface S2 of the substrate 100, the heat transferred to the first electrode 21 is diffused. As a result, the heat dissipation of the VCSEL 10D can be improved.

### SECOND EMBODIMENT

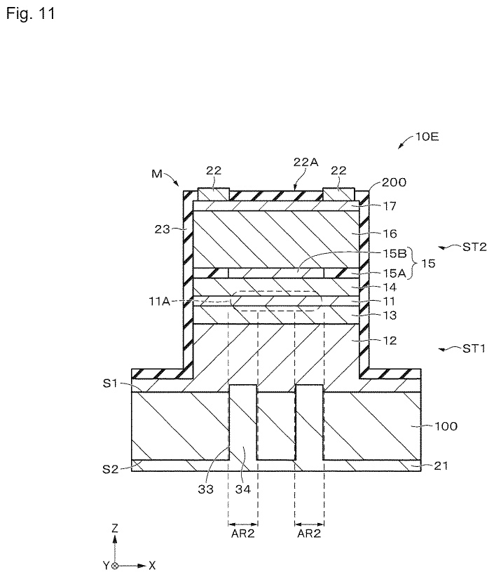

In a second embodiment, any lateral mode that enhances light intensity is an example of a higher order lateral mode. FIG. 11 is a cross-sectional view illustrating an exemplary structure of a VCSEL (VCSEL 10E) according to the second embodiment. The VCSEL 10E according to the present embodiment has a groove 33 connected to the second main surface S2 of the substrate 100 in a facing region facing at least a part of the light emitting region 11A of the active layer 11.

The groove 33 is formed, for example, in a facing region AR2 including a region facing the vicinity of the peripheral edge (peripheral edge portion) including the peripheral edge of the light emitting region 11A. The groove 33 is formed, for example, by excavating the inside of the substrate 100 from the second main surface S2 of the substrate 100, and excavating from the first main surface S1 of the substrate 100 to about several semiconductor layers of the first multilayer film reflector 12. That is, the depth of the groove 33 (the length in the Z direction in FIG. 11) is about the sum of the thickness of the substrate 100 and the number of semiconductor layers of the first multilayer film reflector 12.

A metal portion 34 is provided inside the groove 33. In the present embodiment, the metal portion 34 is provided inside the entire groove 33. The metal portion 34 is made of a metal material having a high reflectance with respect to the laser oscillation wavelength of the VCSEL 10E. The metal portion 34 contains, for example, at least one metal element selected from the group consisting of gold (Au), aluminum (Al), copper (Cu), titanium (Ti), platinum (Pt), palladium (Pd), germanium (Ge), zinc (Zn), silver (Ag), and tungsten (W).

In the present embodiment, the metal portion 34 is connected to the first electrode 21 formed on the second main surface S2 of the substrate 100 (integrally formed). The metal portion 34 is made of, for example, the same metal material as that of the first electrode 21. As a result, when the first electrode 21 is formed on the second main surface S2 of the substrate 100, the metal portion 34 can be formed simultaneously.

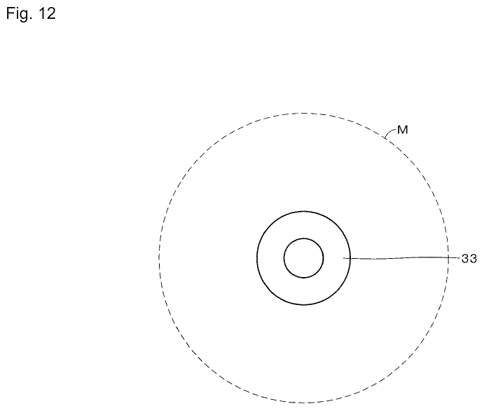

FIG. 12 is a schematic plan view of the VCSEL 10E according to the present embodiment in a plan view. As described above, the annular groove 33 is formed in the facing region AR2 facing the vicinity of the peripheral edge of the light emitting region 11A with respect to the mesa portion M having an isotropic shape. In FIG. 12, only the mesa portion M (dotted line) and the groove 33 (solid line) are illustrated in order to prevent the illustration from being complicated.

The VCSEL 10E is manufactured, for example, by a manufacturing method similar to that of the VCSEL 10D.

### Operation of VCSEL

Next, an operation example of the VCSEL 10E will be described. For example, the current supplied from the anode side of the laser driver and flowing in from the second electrode 22 (anode electrode) passes through the second multilayer film reflector 16, is narrowed in the current confinement region 15A, and is injected into the active layer 11. At this time, the active layer 11 emits light, and the light is amplified by the active layer 11 between the first multilayer film reflector 12 and the second multilayer film reflector 16 and reciprocates while being confined in the current confinement region 15A, and is emitted as laser light from the back surface of the substrate 100 when the oscillation conditions are satisfied. The current that has passed through the active layer 11 reaches the first electrode 21 (cathode electrode) via the first spacer layer 13 and the first multilayer film reflector 12, and flows out from the first electrode 21 to, for example, the cathode side of the laser driver.

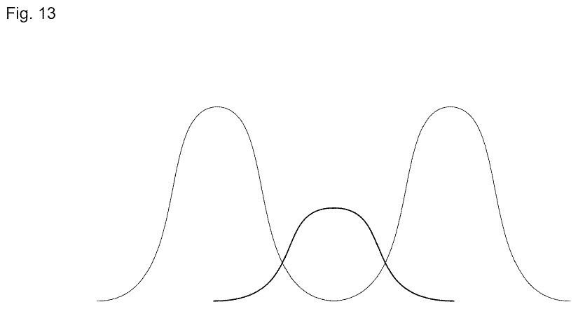

In the present embodiment, the metal portion 34 is formed at a position facing the facing region AR2. The metal portion 34 increases the reflectance of the portion where the metal portion 34 is formed, so that laser oscillation can be easily performed. As a result, the light intensity in the lateral mode corresponding to the portion where the metal portion 34 is formed can be enhanced. Since the facing region AR2 according to the present embodiment is a region facing the vicinity of the peripheral edge of the light emitting region 11A, the light intensity of the higher order lateral mode can be enhanced as schematically illustrated in FIG. 13.

### Effects Obtained in Present Embodiment

According to the VCSEL 10E according to the present embodiment, the following effects can be obtained.

Since the reflectance of the portion where the metal portion 34 is provided can be increased, the light intensity of light in an arbitrary lateral mode, specifically, the higher order lateral mode can be enhanced.

Since the metal portion 34 has a reflectance control structure provided on the side opposite to the light exit port 22A, it is possible to suppress a decrease in light intensity caused by an increase in reflectance at the light exit port 22A as much as possible.

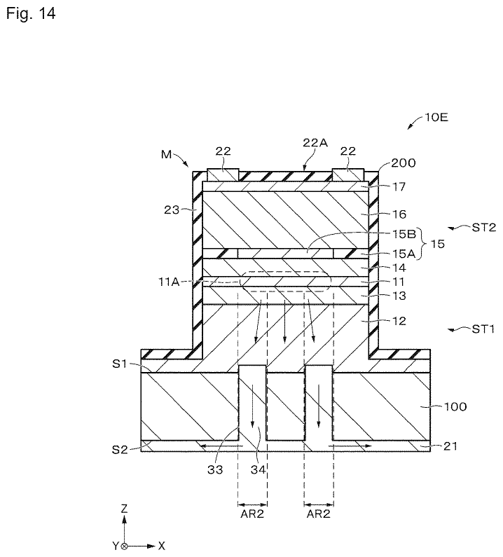

In addition, according to the present embodiment, as in the first embodiment, an excellent heat dissipation function can be obtained. That is, with the structure in which the metal portion 34 is provided in the facing region AR2 facing the vicinity of the peripheral edge of the light emitting region 11A and the metal portion 34 is connected (integrated) with the first electrode 21, the heat generated in the light emitting region 11A can be effectively dissipated. For example, as schematically indicated by an arrow in FIG. 14, heat generated in the light emitting region 11A is transferred to the metal portion 34. The heat transferred to the metal portion 34 is transferred to the first electrode 21. Since the first electrode 21 is formed over the entire second main surface S2 of the substrate 100, the heat transferred to the first electrode 21 is diffused. As a result, the heat dissipation of the VCSEL 10E can be improved.

### THIRD EMBODIMENT

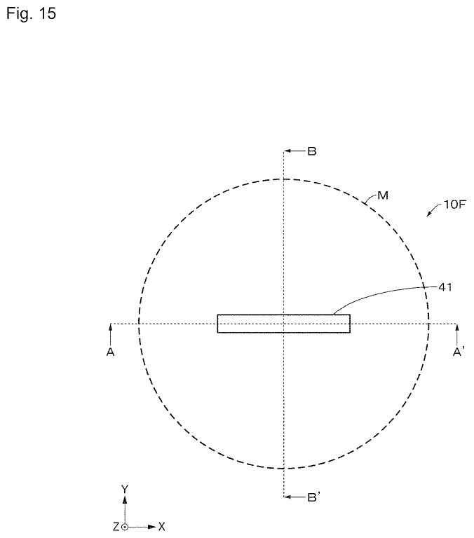

Next, a third embodiment will be described. FIG. 15 is a plan view of a VCSEL (VCSEL 10F) according to the third embodiment. As illustrated in FIG. 15, the VCSEL 10F according to the present embodiment includes a mesa portion M having an isotropic planar shape and a groove 41 having an anisotropic planar shape with respect to the mesa portion M having an isotropic planar shape. In FIG. 15, only the mesa portion M (dotted line) and the groove 41 (solid line) of the VCSEL 10F are illustrated.

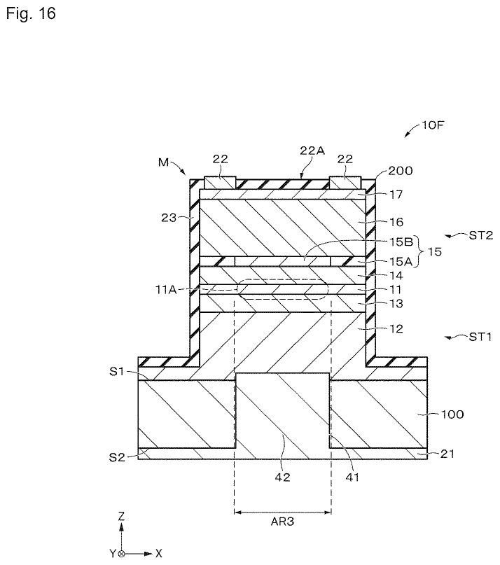

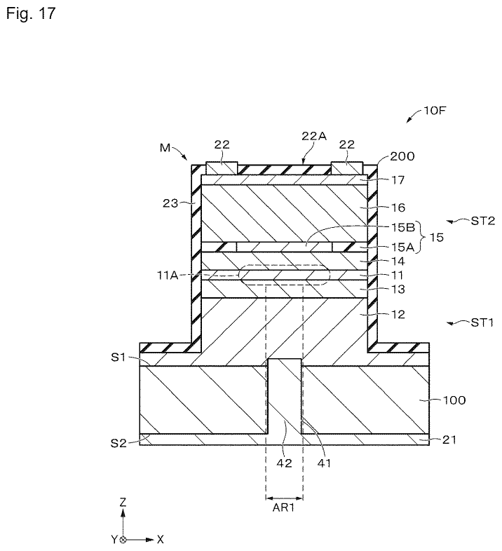

FIG. 16 is a cross-sectional view (in a first cross-sectional view) illustrating a cross section of the VCSEL 10F taken along line A-A′ in FIG. 15. The line A-A′ is a cutting line along the X direction (an example of the first direction) in FIG. 15. In addition, FIG. 17 is a cross-sectional view (in a second cross-sectional view) illustrating a cross section of the VCSEL 10F taken along line B-B′ in FIG. 15. The line B-B′ is a cutting line along the Y direction (an example of the second direction) orthogonal to the X direction in FIG. 15.

The groove 41 is connected to the second main surface S2 of the substrate 100 as in the first embodiment and the second embodiment. The groove 41 is formed, for example, by excavating the inside of the substrate 100 from the second main surface S2 of the substrate 100, and excavating from the first main surface S1 of the substrate 100 to about several semiconductor layers of the first multilayer film reflector 12. That is, the depth of the groove 41 (the length in the Z direction in FIGS. 16 and 17) is about the sum of the thickness of the substrate 100 and the several semiconductor layers of the first multilayer film reflector 12.

A metal portion 42 is provided in the groove 41. In the present embodiment, the metal portion 42 is provided inside the entire groove 41. As the metal element constituting the metal portion 42, the same metal element as the metal portion 32 described above can be applied. The metal portion 42 is connected to the first electrode 21 formed on the second main surface S2 of the substrate 100.

As illustrated in FIG. 16, in the first cross-sectional view, the groove 41 is formed in a facing region AR3 that is a region facing all or substantially all of the light emitting region 11A. On the other hand, as illustrated in FIG. 17, in the second cross-sectional view, the groove 41 is formed in a facing region (for example, the facing region AR1 described in the first embodiment) including a region facing the vicinity of the center of the light emitting region 11A. That is, in the present embodiment, the size of the groove 41 facing the light emitting region 11A is different between in the first cross-sectional view when cut in the X direction and in the second cross-sectional view when cut in the Y direction orthogonal to the X direction.

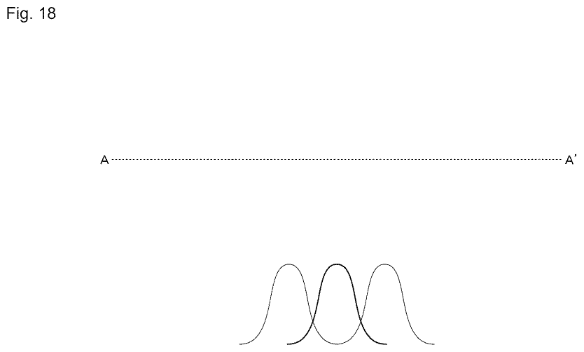

FIG. 18 illustrates a lateral mode characteristic in the long axis direction (X direction) of the laser light emitted from the VCSEL 10F. In the X direction, the groove 41 is formed so as to face the entire region of the light emitting region 11A, and the metal portion 42 is provided in the groove 41. Therefore, as illustrated in FIG. 18, the light intensity of the basic lateral mode and the light intensity of the higher order lateral mode can be enhanced by the metal portion 42.

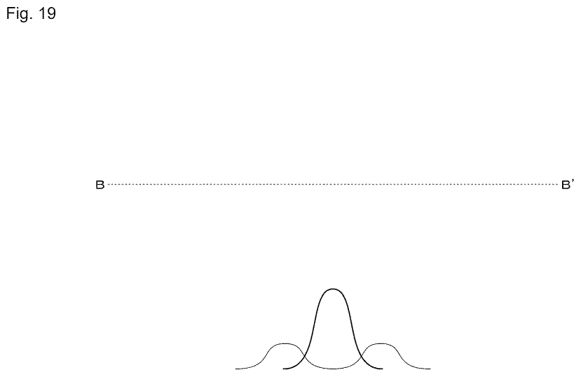

FIG. 19 illustrates a lateral mode characteristic in the short axis direction (Y direction) of the laser light emitted from the VCSEL 10F. In the Y direction, the groove 41 is formed so as to face a region including the vicinity of the center of the light emitting region 11A, and the metal portion 42 is provided in the groove 41. Therefore, as illustrated in FIG. 19, the light intensity of the basic lateral mode can be enhanced more than the light intensity of the higher order lateral mode by the metal portion 42.

According to the present embodiment, the lateral mode characteristics of the laser light can be changed in different directions. Therefore, an anisotropic light emission pattern reflecting the shape of the groove 41 can be formed.

Furthermore, by making the long axis direction and the short axis direction of the groove having an anisotropic shape correspond to the light emission intensity distributions in the two orthogonal polarization directions of the VCSEL 10F, respectively, it is possible to perform polarization control with a difference in light intensity between polarized light.

Since the metal portion 42 has a reflectance control structure provided on the side opposite to the light exit port 22A, it is possible to suppress a decrease in light intensity caused by an increase in reflectance at the light exit port 22A as much as possible.

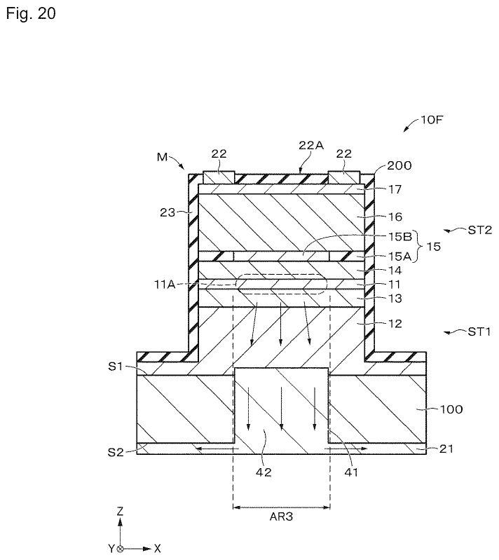

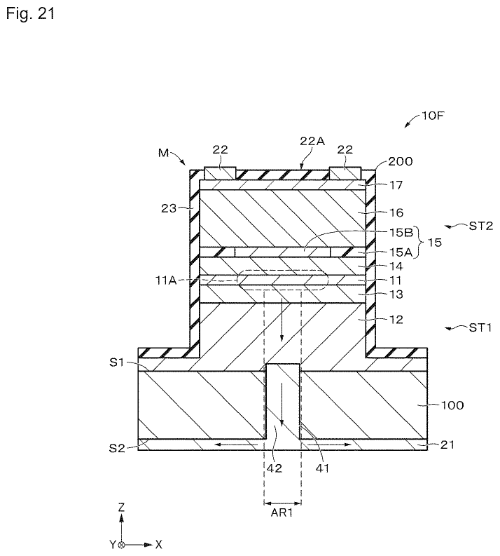

In addition, as schematically indicated by arrows in FIGS. 20 and 21, also according to the present embodiment, heat generated in the light emitting region 11A can be diffused over the first electrode 21 via the metal portion 42. Therefore, the heat dissipation of the light emitting device can be improved.

As described above, according to the first to third embodiments, it is possible to control an arbitrary lateral mode depending on the position and shape of the groove. Accordingly, a light emitting device having a lateral mode characteristic suitable for a desired application can be realized.

### MODIFICATION

Although the embodiments of the present technology have been specifically described above, the content of the present technology is not limited to the above-described embodiments, and various modifications based on the technical idea of the present technology are possible. Note that configurations identical or similar to those of the embodiments are denoted by the same reference numerals, and redundant description will be omitted as appropriate.

### First Modification

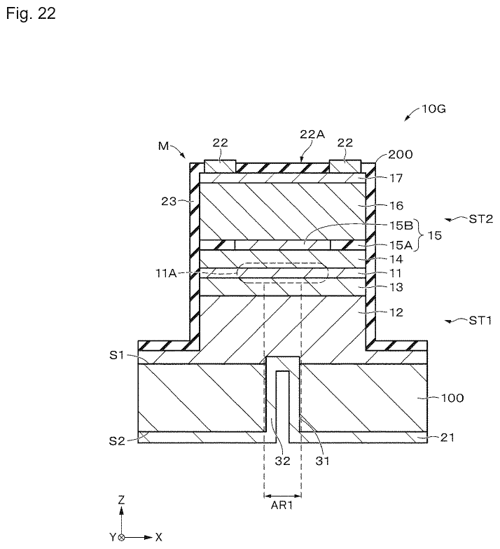

FIG. 22 is a cross-sectional view illustrating an exemplary structure of a VCSEL (VCSEL 10G) according to a first modification. In the above-described embodiment, the metal portion is formed so as to fill the entire inside of the groove, but the metal portion may be formed in a part of the inside of the groove. For example, as illustrated in FIG. 22, the metal portion 32 described in the first embodiment may be a metal layer formed in layers on the inner surface of the groove 31. Even in this case, it is preferable that the layered metal portion 32 is connected to the first electrode 21 from the viewpoint of improving heat dissipation. Similarly, the metal portion 34 and the metal portion 42 may also be metal layers formed in layers on the inner surface of the groove. According to the present modification, effects similar to the effects described in the embodiment can be obtained.

### Second Modification

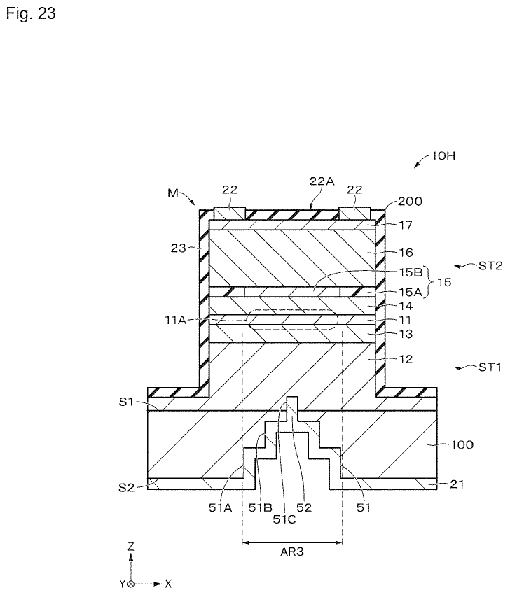

The present modification is an example in which the groove is configured by a plurality of grooves. FIG. 23 is a cross-sectional view illustrating an exemplary structure of a VCSEL (VCSEL 10H) according to a second modification. The VCSEL 10H has, for example, a groove 51 connected to the second main surface S2 of the substrate 100.

The groove 51 includes, for example, a first groove 51A, a second groove 51B, and a third groove 51C. Specifically, the groove 51 has a shape in which the first groove 51A, the second groove 51B, and the third groove 51C are continuously formed from the second main surface S2 side of the substrate 100. The first groove 51A and the second groove 51B are formed in the substrate 100, and the third groove 51C is formed from the substrate 100 to about several semiconductor layers of the first multilayer film reflector 12.

The groove 51 has a shape in which the width (length in the X direction in the drawing) of each groove from the first groove 51A to the third groove 51C decreases from the second main surface S2 toward the first main surface S1 of the substrate 100. The depth (length in the Z direction in the drawing) of each groove may be different. For example, the groove 51 is obtained by forming the first groove 51A by excavating the substrate 100 to a predetermined depth, then forming the second groove 51B by excavating the substrate 100 to a predetermined depth, and finally forming the third groove 51C by excavating the substrate 100 to a predetermined depth (for example, a depth reaching about several semiconductor layers of the first multilayer film reflector 12).

A metal portion 52 is formed inside the groove 51. The metal portion 52 has, for example, a shape in which a metal portion formed in a layer shape on the inner surface of the first groove 51A, a metal portion formed in a layer shape on the inner surface of the second groove 51B, and a metal portion formed over the entire inside of the third groove 51C are continuously formed. The metal portion 52 is connected to the first electrode 21 formed on the second main surface S2 of the substrate 100.

The same effects as those of the embodiment can be obtained by the present modification. Furthermore, according to the present modification, even in a case where the thickness of the substrate 100 is large and the groove cannot be formed by removal by one-time etching, it is possible to realize the structure of the VCSEL in which the above-described effect can be obtained.

### Third Modification

Configuration Example of Surface-Emitting Laser to Which Present Technology Can Be Applied

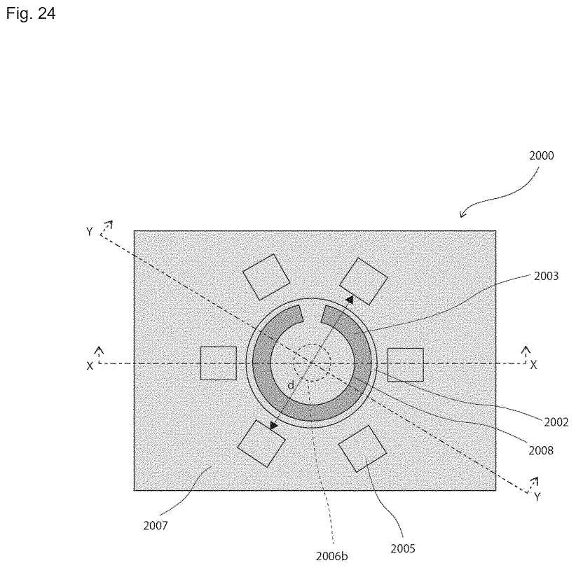

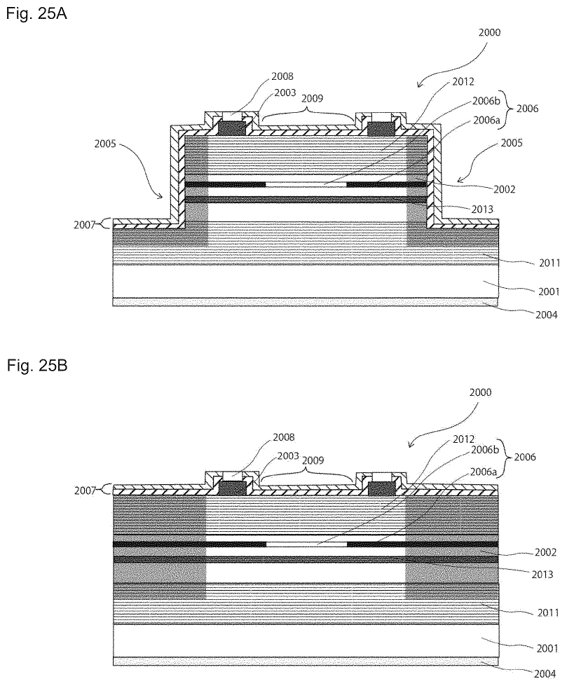

FIG. 24 is a plan view illustrating a surface-emitting laser 2000, which is a configuration example of a surface-emitting laser to which the present technology can be applied. FIG. 25A is a cross-sectional view taken along line X-X of FIG. 24. FIG. 25B is a cross-sectional view taken along line Y-Y in FIG. 24.

Each component of the surface-emitting laser 2000 is stacked on a substrate 2001. The substrate 2001 can include, for example, a semiconductor such as GaAs, InGaAs, InP, or InAsP.

The surface-emitting laser 2000 includes a protective region 2002 (a transmissive gray region in FIGS. 25A and 25B). As illustrated in FIG. 24, the protective region 2002 has a circular shape in a plan view, but is not limited to a particular shape and may have another shape, such as an elliptical shape or a polygonal shape. The protective region 2002 includes a material that provides electrical isolation, for example, a region where ions are implanted.

As illustrated in FIGS. 25A and 25B, the surface-emitting laser 2000 also includes a first electrode 2003 and a second electrode 2004. As illustrated in FIG. 24, the first electrode 2003 has a ring shape having discontinuous portions (intermittent portions) in a plan view, that is, a split ring shape, but is not limited to a specific shape. As illustrated in FIG. 25A or 25B, the second electrode 2004 is in contact with the substrate 2001. The first electrode 2003 and the second electrode 2004 include, for example, a conductive material such as Ti, Pt, Au, AuGeNi, or PdGeAu. The first electrode 2003 and the second electrode 2004 may have a single-layer structure or a stacked structure.

Furthermore, the surface-emitting laser 2000 includes trenches 2005 provided around the protective region 2002. FIG. 24 illustrates, as an example, a structure in which rectangular trenches 2005 are provided in six places in a plan view. However, the number of trenches and the shape of each trench in a plan view are not limited to a specific one. The trench 2005 is an opening for forming an oxide-confinement layer 2006 (including an oxidized region 2006a and a non-oxidized region 2006b). In the process of manufacturing the surface-emitting laser 2000, high-temperature water vapor is supplied through the trenches 2005 to form the oxidized region 2006a of the oxide-confinement layer 2006. For example, the oxidized region 2006a is Al2O3 formed as a result of the oxidation of the AlAs or AlGaAs layer. The trench 2005 may be filled with an optional dielectric material after the step of forming the oxide-confinement layer 2006.

In some cases, the surface is coated with a dielectric film.

Furthermore, the surface-emitting laser 2000 includes a dielectric opening 2008 (contact hole) provided in a dielectric layer 2007 on the first electrode 2003. The dielectric layer 2007 may have a stacked structure as illustrated in FIGS. 25A and 25B, or may have a single-layer structure. The dielectric layer 2007 contains, as an example, silicon oxide or silicon nitride. As illustrated in FIG. 24, the dielectric opening 2008 is formed in the same shape as the first electrode 2003. However, the shape of the dielectric opening 2008 is not limited to the shape of the first electrode 2003, and may be formed partially on the first electrode 2003. The dielectric opening 2008 is filled with a conductive material (not illustrated), which is in contact with the first electrode 2003.

Furthermore, as illustrated in FIGS. 25A and 25B, the surface-emitting laser 2000 includes an optical aperture 2009 inside of the first electrode 2003. The surface-emitting laser 2000 emits a beam of light through the optical aperture 2009.

Furthermore, in the surface-emitting laser 2000, the oxidized region 2006a of the oxide-confinement layer 2006 functions as a current and light confining region that confines current and light. The non-oxidized region 2006b of the oxide-confinement layer 2006 is located below the optical aperture 2009, and functions as a current and light passing region that allows current and light to pass therethrough.

Furthermore, the surface-emitting laser 2000 includes a first multilayer film reflector 2011 and a second multilayer film reflector 2012. The multilayer film reflector is, as an example, a semiconductor multilayer film reflector, which is also called a distributed Bragg reflector.

Furthermore, the surface-emitting laser 2000 includes an active layer 2013. The active layer 2013 is disposed between the first multilayer film reflector 2011 and the second multilayer film reflector 2012, and confines the injected carriers and determines the emission wavelength of the surface-emitting laser 2000.

In this configuration example, a case has been described, as an example, in which the surface-emitting laser 2000 is a surface-emitting laser of front-emitting type. However, the surface-emitting laser 2000 can also be a surface-emitting laser of back-emitting type.

As illustrated in FIGS. 24 and 25A, the substantial diameter of the surface-emitting laser 2000 of this configuration example is a diameter d of an imaginary circle defined by the trenches 2005.

The surface-emitting laser 2000 of this configuration example is manufactured, as an example, by the following steps 1 to 8.
(Step 1) On the surface of the substrate 2001, the first multilayer film reflector 2011, the active layer 2013, a selectively oxidized layer which will become the oxide-confinement layer 2006, and the second multilayer film reflector 2012 are epitaxially grown.
(Step 2) The first electrode 2003 is formed on the second multilayer film reflector 2012 by, for example, a lift-off method.
(Step 3) The trenches 2005 are formed by, for example, photolithography.
(Step 4) The side surface of the selectively oxidized layer is exposed, and the selectively oxidized layer is selectively oxidized from the side surface to form the oxide-confinement layer 2006.
(Step 5) The protective region 2002 is formed by ion implantation or the like.
(Step 6) The dielectric layer 2007 is formed by, for example, deposition, sputtering, or the like.
(Step 7) The dielectric opening 2008 is formed in the dielectric layer 2007 by, for example, photolithography, to expose the contact of the first electrode 2003.
(Step 8) After the back surface of the substrate 2001 is polished to make it thinner, the second electrode 2004 is formed on the back surface of the substrate 2001.

The above-described number of layers, arrangement, thickness, order of arrangement, symmetry, and the like, which configure the surface-emitting laser 2000 are merely examples and can be modified as appropriate. In other words, the surface-emitting laser 2000 may include more layers, fewer layers, different layers, layers with different structures, or layers in different arrangements than those illustrated in FIGS. 24, 25A, and 25B.

The present technology can be applied to the above-described surface-emitting laser 2000 and its modification examples.

### Other Modifications

In the above-described embodiment, the metal portion and the first electrode are preferably connected from the viewpoint of improving heat dissipation, but may be separated. For example, in the case of a VCSEL in which the first electrode is provided on the side surface of the mesa portion in a state of being insulated from the second electrode, the metal portion inside the groove and the first electrode may be separated from each other. Furthermore, the present technology can also be applied to a light emitting device having a light emitting unit having a structure different from that of the VCSEL.

In the above-described embodiment, the metal portion and the second electrode have been described as the same type of metal material, but the metal materials constituting the metal portion and the second electrode may be different from each other. In addition, the metal portion and the second electrode may be formed in different steps instead of the same step.

In the above-described embodiment, the depth of the groove may not reach the first multilayer film reflector but may reach the substrate. However, from the viewpoint of improving reflection efficiency and heat dissipation in the metal portion, it is preferable that the metal portion is closer to the light emitting region (structure in which the depth of the groove reaches the first multilayer film reflector).

Note that the effects described in the present specification are merely exemplary and not intended to be limiting, and other effects may be provided as well.

Note that the present technology can also have the following configurations.
(1)

A light emitting device including:
a substrate having a first main surface and a second main surface on an opposite side thereof to the first main surface; and
a light emitting unit formed on the first main surface of the substrate, the light emitting unit includes:
a first structure that includes a first multilayer film reflector;
a second structure that includes a second multilayer film reflector; and
an active layer that is disposed between the first structure and the second structure,
a groove connected to the second main surface of the substrate is formed in a facing region facing at least a part of a light emitting region of the active layer, and
a metal portion is formed inside the groove.

The light emitting device according to (1), including:
a first electrode connected to the first structure; and
a second electrode formed on the second main surface,
the metal portion is connected to the second electrode.
(3)

The light emitting device according to (1) or (2), in which
the groove is formed in a facing region facing a substantially center of the light emitting region.
(4)

The light emitting device according to (1) or (2), in which the groove is formed in a facing region facing a peripheral edge of the light emitting region.
(5)

The light emitting device according to (1) or (2), in which
a size of the groove facing the light emitting region is different between in a first cross-sectional view when being cut in a first direction and in a second cross-sectional view when being cut in a second direction orthogonal to the first direction.
(6)

The light emitting device according to (5), in which
the light emitting region and the groove face each other in the first cross-sectional view, and
a substantially center of the light emitting region and the groove face each other in the second cross-sectional view.
(7)

The light emitting device according to (5) or (6), in which
light emission intensity distributions of polarized light orthogonal to each other are different.
(8)

The light emitting device according to (1), in which
the groove has a shape in which a width decreases from the second main surface to the first main surface.
(9)

The light emitting device according to any one of (1) to (8), in which
the metal portion is formed entirely inside the groove.
(10)

The light emitting device according to any one of (1) to (8), in which
the metal portion is a metal layer formed in a layer shape on an inner surface of the groove.
(11)

The light emitting device according to any one of (1) to (10), in which
the groove is formed inside the substrate and across the second multilayer film reflector.
(12)

The light emitting device according to (2), in which the metal portion and the second electrode contain the same kind of metal element.
(13)

The light emitting device according to any one of (1) to (12), in which
the metal portion contains at least one metal element selected from the group consisting of gold (Au), aluminum (Al), copper (Cu), titanium (Ti), platinum (Pt), palladium (Pd), germanium (Ge), zinc (Zn), silver (Ag), and tungsten (W).

### APPLICATION EXAMPLE

A technique according to the present technology is not limited to the foregoing application example and can be applied to various products. For example, the technique according to the present disclosure may be implemented as an apparatus mounted on any kind of mobile body such as an automobile, an electric vehicle, a hybrid electric vehicle, a motorcycle, a bicycle, a personal mobility, an airplane, a drone, a ship, a robot, a construction machine, or an agricultural machine (tractor).

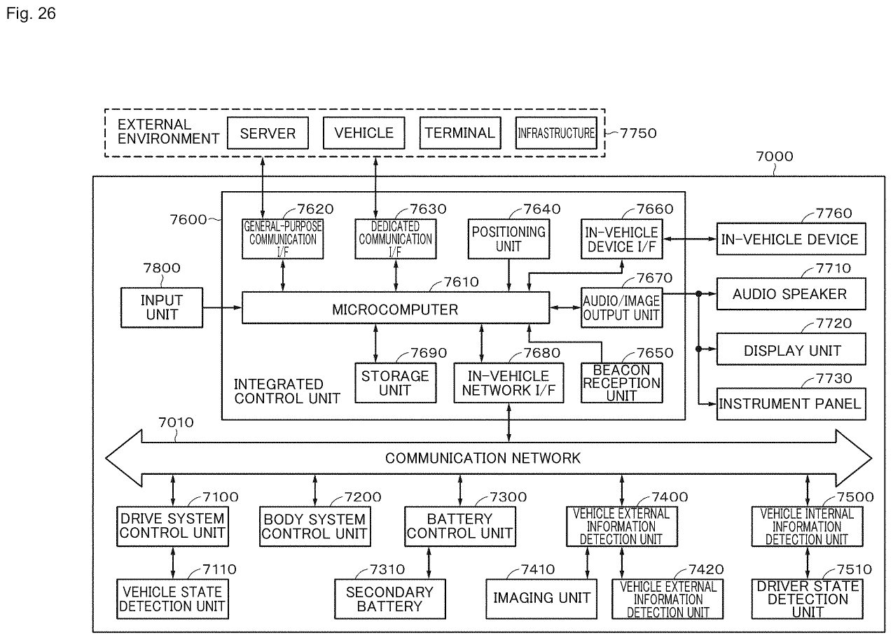

FIG. 26 is a block diagram illustrating a schematic configuration example of a vehicle control system 7000 that is an example of a mobile control system to which a technique according to the present technology is applicable. The vehicle control system 7000 includes a plurality of electronic control units connected via a communication network 7010. In the example illustrated in FIG. 26, the vehicle control system 7000 includes a drive system control unit 7100, a body system control unit 7200, a battery control unit 7300, a vehicle external information detection unit 7400, a vehicle internal information detection unit 7500, and an integrated control unit 7600. The communication network 7010 connecting the plurality of control units may be, for example, an in-vehicle communication network compliant with any standards such as controller area network (CAN), local interconnect network (LIN), local area network (LAN), and FlexRay (registered trademark).

Each control unit includes a microcomputer that performs arithmetic processing according to various programs, a storage unit that stores programs executed by the microcomputer or parameters or the like used for various arithmetic operations, and a drive circuit that drives various devices to be controlled. Each control unit includes a network I/F for performing communication with another control unit via the communication network 7010, and a communication I/F for performing communication with devices or sensors inside or outside of the vehicle through wired communication or wireless communication. FIG. 26 illustrates a microcomputer 7610, a general-purpose communication I/F 7620, a dedicated communication I/F 7630, a positioning unit 7640, a beacon reception unit 7650, an in-vehicle device I/F 7660, an audio/image output unit 7670, an in-vehicle network I/F 7680, and a storage unit 7690 as a functional configuration of the integrated control unit 7600. Other control units also include a microcomputer, a communication I/F, a storage unit, and the like likewise.

The drive system control unit 7100 controls the operations of devices related to the drive system of the vehicle according to various programs. For example, the drive system control unit 7100 functions as a control device for a driving force generation device for generating a vehicle driving force of an internal combustion engine or a drive motor, a driving force transmission mechanism for transmitting the driving force to wheels, a steering mechanism for adjusting a steering angle of the vehicle, and a braking device that generates a braking force of the vehicle. The drive system control unit 7100 may have a function as a control device, for example, an antilock brake system (ABS) or electronic stability control (ESC).

The drive system control unit 7100 is connected with a vehicle state detection unit 7110. The vehicle state detection unit 7110 includes, for example, at least one of a gyro sensor that detects an angular velocity of an axial rotation motion of a vehicle body, an acceleration sensor that detects an acceleration of a vehicle, and a sensor that detects, for example, an operation amount of an acceleration pedal, an operation amount of a brake pedal, a steering angle of a steering wheel, an engine speed, or a wheel rotation speed or the like. The drive system control unit 7100 performs arithmetic processing using a signal input from the vehicle state detection unit 7110 and controls an internal combustion engine, a driving motor, an electric power steering device, or a brake device or the like.

The body system control unit 7200 controls operations of various devices equipped to the vehicle body according to various programs. For example, the body system control unit 7200 functions as a control device of a keyless entry system, a smart key system, a power window device, or various lamps such as a headlamp, a back lamp, a brake lamp, a turn indicator, and a fog lamp. In this case, the body system control unit 7200 can receive input of radio waves emitted from a portable device in place of a key or signals of various switches. The body system control unit 7200 receives the input of radio waves or signals and controls a door lock device, a power window device, and a lamp of the vehicle.

The battery control unit 7300 controls a secondary battery 7310 that is a power supply source of a driving motor according to various programs. For example, the battery control unit 7300 receives from a battery device including the secondary battery 7310 input of information such as a battery temperature, a battery output voltage, or a remaining capacity of a battery. The battery control unit 7300 performs arithmetic processing using such a signal and performs temperature adjustment control of the secondary battery 7310 or control of a cooling device equipped to the battery device.

The vehicle external information detection unit 7400 detects information outside of the vehicle in which the vehicle control system 7000 is mounted. For example, at least one of an imaging unit 7410 and a vehicle external information detection unit 7420 is connected to the vehicle external information detection unit 7400. The imaging unit 7410 includes at least one of a Time of Flight (ToF) camera, a stereo camera, a monocular camera, an infrared camera, and other cameras. The vehicle external information detection unit 7420 includes at least one of, for example, an environmental sensor that detects the present weather or atmospheric phenomena and a surrounding information detection sensor that detects other vehicles, obstacles, or pedestrians around a vehicle where the vehicle control system 7000 is mounted.

The environmental sensor may be, for example, at least one of a raindrop sensor that detects rainy weather, a fog sensor that detects fog, a sunshine sensor that detects the degree of sunshine, and a snow sensor that detects snowfall. The surrounding information detection sensor may be at least one of an ultrasonic sensor, a radar device, and a LIDAR (Light Detection and Ranging, Laser Imaging Detection and Ranging) device. The imaging unit 7410 and the vehicle external information detection unit 7420 may be included as independent sensors or devices or may be included as a device in which a plurality of sensors or devices are integrated.

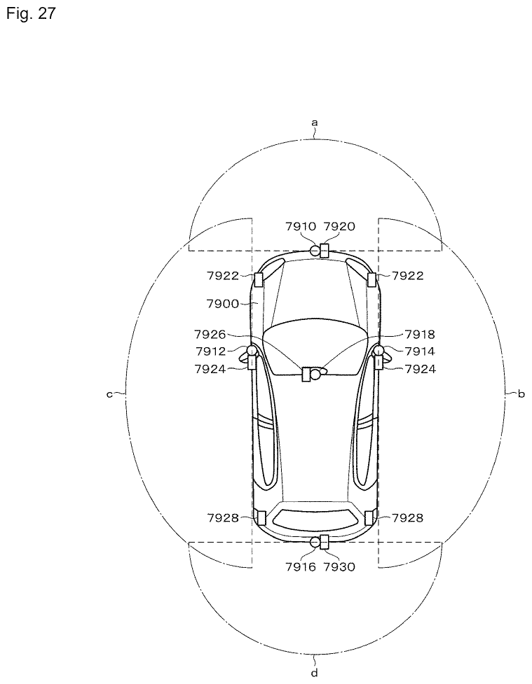

FIG. 27 illustrates an example of installation positions of the imaging unit 7410 and the vehicle external information detection unit 7420. Imaging units 7910, 7912, 7914, 7916, and 7918 are provided, for example, at least one of a front nose, side mirrors, a rear bumper, a back door, and an upper part of a windshield in a vehicle cabin of the vehicle 7900. The imaging unit 7910 provided on the front nose and the imaging unit 7918 provided in the upper portion of the windshield inside of the vehicle mainly acquire images on the front side of the vehicle 7900. The imaging units 7912 and 7914 provided on the side mirrors mainly acquire images on the lateral sides of the vehicle 7900. The imaging unit 7916 provided on the rear bumper or the backdoor mainly acquires images on the rear side of the vehicle 7900. The imaging unit 7918 included in the upper part of the windshield in the vehicle cabin is mainly used for the detection of a preceding vehicle, a pedestrian, an obstacle, a traffic light, a traffic sign, a lane, or the like.

FIG. 27 shows an example of the imaging ranges of the imaging units 7910, 7912, 7914, and 7916. An imaging range a indicates an imaging range of the imaging unit 7910 provided to the front nose, imaging ranges b and c indicate imaging ranges of the imaging units 7912 and 7914 provided to the side mirrors, and an imaging range d indicates an imaging range of the imaging unit 7916 provided to the rear bumper or the back door. For example, by superimposing image data captured by the imaging units 7910, 7912, 7914, and 7916, it is possible to obtain a bird's eye view image seen from above the vehicle 7900.

Vehicle external information detection units 7920, 7922, 7924, 7926, 7928, and 7930 provided on the front, rear, sides, corners, and an upper part of the windshield in the vehicle 7900 may be, for example, ultrasonic sensors or radar devices. The vehicle external information detection units 7920, 7926, and 7930 provided on the front nose, rear bumper, back door, and upper part of the windshield in the vehicle 7900 may be, for example, LIDAR devices. These vehicle external information detection units 7920 to 7930 are mainly used for detecting vehicles ahead, pedestrians, or obstacles and the like.

The explanation will be continued with reference to FIG. 26 again. The vehicle external information detection unit 7400 causes the imaging unit 7410 to capture an image of the outside of the vehicle and receives captured image data.

Furthermore, the vehicle external information detection unit 7400 receives detection information from the connected vehicle external information detection unit 7420. When the vehicle external information detection unit 7420 is an ultrasonic sensor, a radar device, or an LIDAR device, the vehicle external information detection unit 7400 transmits ultrasonic waves or electromagnetic waves and the like and receives information on received reflected waves. The vehicle external information detection unit 7400 may perform object detection processing or distance detection processing for a person, a vehicle, an obstacle, a sign, a character on a road surface, or the like based on the received information. The vehicle external information detection unit 7400 may perform environment recognition processing for recognizing rainfall, fog, or a road surface situation and the like on the basis of the received information. The vehicle external information detection unit 7400 may calculate a distance to an object outside of the vehicle on the basis of the received information.

Furthermore, the vehicle external information detection unit 7400 may perform image recognition processing or distance detection processing for recognizing a person, a vehicle, an obstacle, a sign, or a character on a road surface on the basis of the received image data. The vehicle external information detection unit 7400 may perform processing such as distortion correction or alignment on the received image data, and combine image data captured by the different imaging units 7410 to generate a bird's-eye view image or a panoramic image. The vehicle external information detection unit 7400 may perform viewpoint conversion processing using the image data captured by the different imaging units 7410.

The vehicle internal information detection unit 7500 detects information inside of the vehicle. For example, a driver state detection unit 7510 that detects a driver's state is connected to the vehicle internal information detection unit 7500. The driver state detection unit 7510 may include a camera that captures an image of a driver, a biological sensor that detects biological information of the driver, or a microphone that collects sound in the vehicle. The biological sensor is provided on, for example, a seat surface or a steering wheel, and detects biological information about a passenger on a seat or a driver holding the steering wheel. The vehicle internal information detection unit 7500 may calculate the degree of fatigue or the degree of concentration of the driver or determine whether or not the driver is drowsing based on detection information input from the driver state detection unit 7510. The vehicle internal information detection unit 7500 may perform noise cancellation processing or the like on a collected sound signal.

The integrated control unit 7600 controls overall operations in the vehicle control system 7000 according to various programs. An input unit 7800 is connected to the integrated control unit 7600. The input unit 7800 is implemented by a device that can be operated for the input by a passenger, for example, a touch panel, a button, a microphone, a switch, or a lever. Data obtained by recognizing voice inputted through a microphone may be inputted to the integrated control unit 7600. The input unit 7800 may be, for example, a remote control device using infrared rays or other radio waves, or may be an externally connected device such as a mobile phone or a personal digital assistant (PDA) in response to an operation on the vehicle control system 7000. The input unit 7800 may be, for example, a camera, and, in this case, the passenger can input information by gesture thereto. Alternatively, data obtained by detecting a motion of a wearable device worn by a passenger may be input. Furthermore, the input unit 7800 may include, for example, an input control circuit that generates an input signal based on information input by the passenger or the like using the above input unit 7800 and outputs the input signal to the integrated control unit 7600. The passenger or the like inputs various types of data to the vehicle control system 7000 or provides an instruction about a processing operation by operating the input unit 7800.

The storage unit 7690 may include a read only memory (ROM) that stores various programs to be executed by a microcomputer, and a random access memory (RAM) that stores various parameters, calculation results, or sensor values or the like. The storage unit 7690 may be implemented by, for example, a magnetic storage device such as a hard disc drive (HDD), a semiconductor storage device, an optical storage device, or a magneto-optical storage device.

The general-purpose communication I/F 7620 is a general-purpose communication interface that mediates communication with various devices present in an external environment 7750. The general-purpose communication I/F 7620 may have, implemented therein, a cellular communication protocol such as Global System of Mobile Communications (GSM (registered trademark)), WiMAX (registered trademark), Long Term Evolution (LTE (registered trademark)), or LTE-Advanced (LTE-A), or other wireless communication protocols such as wireless LAN (also referred to as Wi-Fi (registered trademark)) or Bluetooth (registered trademark). The general-purpose communication I/F 7620 may be connected to, for example, a device (for example, an application server or a control server) present on an external network (for example, the Internet, a cloud network, or a business-specific network) via a base station or an access point. The general-purpose communication I/F 7620 may be connected to terminals (for example, the terminals of the driver, pedestrians, or shops, or Machine Type Communication (MTC) terminals) near the vehicle by using, for example, the peer to peer (P2P) technique.

The dedicated communication I/F 7630 is a communication interface supporting a communication protocol formulated for the purpose of use in a vehicle. The dedicated communication I/F 7630 may implement, for example, a standard protocol such as a wireless access in vehicle environment (WAVE) that is a combination of IEEE802.11p of a lower layer and IEEE1609 of an upper layer, a dedicated short range communications (DSRC), or a cellular communication protocol. The dedicated communication I/F 7630 typically performs V2X communications as a concept including one or more of vehicle-to-vehicle communications, vehicle-to-infrastructure communications, vehicle-to-home communications, and vehicle-to-pedestrian communications.

The positioning unit 7640 receives, for example, a GNSS signal from a global navigation satellite system (GNSS) satellite (for example, a GPS signal from a global positioning system (GPS) satellite), executes positioning, and generates position information including a latitude, longitude, and altitude of the vehicle. Note that the positioning unit 7640 may specify a current position by exchanging signals with a wireless access point, or may acquire position information from a terminal such as a mobile phone, a PHS, or a smartphone having a positioning function.

The beacon reception unit 7650 receives radio waves or electromagnetic waves transmitted from a radio station or the like installed on a road, and acquires information such as a current position, traffic jam, no throughfare, or a required time. Note that the function of the beacon reception unit 7650 may be included in the above-described dedicated communication I/F 7630.

The in-vehicle device I/F 7660 is a communication interface that mediates connections between the microcomputer 7610 and various in-vehicle devices 7760 present in the vehicle. The in-vehicle device I/F 7660 may establish a wireless connection using wireless communication protocols such as a wireless LAN, Bluetooth (registered trademark), near field communication (NFC), and Wireless USB (WUSB). Furthermore, the in-vehicle device I/F 7660 may establish a wired connection of, for example, a Universal Serial Bus (USB), High-Definition Multimedia Interface (HDMI (registered trademark)), or Mobile High-definition Link (MHL) via a connection terminal (and a cable if necessary), which is not illustrated. The in-vehicle device 7760 may include, for example, at least one of a mobile device or a wearable device of the passenger and an information device carried in or attached to the vehicle. Furthermore, the in-vehicle device 7760 may include a navigation device that searches for a route to any destination. The in-vehicle device I/F 7660 exchanges control signals or data signals with the in-vehicle device 7760.

The in-vehicle network I/F 7680 is an interface that mediates communications between the microcomputer 7610 and the communication network 7010. The in-vehicle network I/F 7680 transmits and receives signals or the like in conformity with a predetermined protocol supported by the communication network 7010.

The microcomputer 7610 of the integrated control unit 7600 controls the vehicle control system 7000 in accordance with various programs based on information acquired through at least one of the general-purpose communication I/F 7620, the dedicated communication I/F 7630, the positioning unit 7640, the beacon reception unit 7650, the in-vehicle device I/F 7660, and the in-vehicle network I/F 7680. For example, the microcomputer 7610 may calculate control target values for a driving force generation device, a steering mechanism, or a braking device based on acquired information on the inside and outside of the vehicle, and output control commands to the drive system control unit 7100. For example, the microcomputer 7610 may perform cooperative control for the purpose of implementing the functions of advanced driver assistance system (ADAS), the functions including vehicle collision avoidance or impact mitigation, follow-up traveling based on an inter-vehicle distance, vehicle speed maintenance driving, a vehicle collision warning, and a vehicle lane departure warning. The microcomputer 7610 may perform coordinated control for automated driving in which a vehicle travels in an automated manner regardless of an operation of a driver, by controlling, for example, a driving force generation device, a steering mechanism, or a braking device based on acquired surrounding information on the vehicle.

The microcomputer 7610 may generate 3-dimensional distance information between the vehicle and objects such as surrounding structures or people based on information acquired via at least one of the general-purpose communication I/F 7620, the dedicated communication I/F 7630, the positioning unit 7640, the beacon reception unit 7650, the in-vehicle device I/F 7660, and the in-vehicle network I/F 7680, and may generate local map information including surrounding information of a present position of the vehicle. The microcomputer 7610 may predict a danger such as collision of the vehicle, approach of a pedestrian, or entry into a closed road on the basis of the acquired information and may generate a warning signal. For example, the warning signal may be a signal for generating a warning sound or turning on a warning lamp.

The audio/image output unit 7670 transmits output signals of at least one of the audio and images to an output device capable of visually or audibly notifying a passenger of the vehicle or the outside of the vehicle of information. In the example of FIG. 26, an audio speaker 7710, a display unit 7720, and an instrument panel 7730 are illustrated as output devices. For example, the display unit 7720 may include at least one of an on-board display and a head-up display. The display unit 7720 may have an augmented reality (AR) display function. The output device may be other devices such as a headphone, a wearable device such as a glasses-type display worn by a passenger, a projector, or a lamp. When the output device is a display device, the display device visually displays results obtained through various processing performed by the microcomputer 7610 or information received from another control unit in various formats such as text, images, tables, and graphs. When the output device is a sound output device, the sound output device converts an audio signal including reproduced sound data or acoustic data into an analog signal and outputs the analog signal auditorily.

Note that, in the example illustrated in FIG. 26, at least two control units connected via the communication network 7010 may be integrated as one control unit. Alternatively, each control unit may be composed of a plurality of control units. Furthermore, the vehicle control system 7000 may include another control unit (not illustrated). In the foregoing description, some or all of the functions of any one of the control units may be included in another control unit. In other words, predetermined arithmetic processing may be performed by any one of the control units as long as information is transmitted and received via the communication network 7010. Similarly, a sensor or device connected to any one of the control units may be connected to another control unit, and a plurality of control units may mutually transmit or receive detection information via the communication network 7010.

In the foregoing vehicle control system 7000, the light emitting device of the present technology is applicable to, for example, the vehicle external information detection unit.

### REFERENCE SIGNS LIST

10A to 10H VCSEL
11 Active layer
11A Light emitting region
12 First multilayer film reflector
16 Second multilayer film reflector
21 First electrode
22 Second electrode
31, 33, 41, 52 Groove
32, 34, 42, 53 Metal portion
100 Substrate
ST1 First structure
ST2 Second structure
S1 First main surface
S2 Second main surface

1. A light emitting device comprising:
a substrate having a first main surface and a second main surface on an opposite side thereof to the first main surface; and
a light emitting unit formed on the first main surface of the substrate, wherein
the light emitting unit includes:
a first structure that includes a first multilayer film reflector;
a second structure that includes a second multilayer film reflector; and
an active layer that is disposed between the first structure and the second structure,
wherein
a groove connected to the second main surface of the substrate is formed in a facing region facing at least a part of a light emitting region of the active layer, and
a metal portion is formed inside the groove.

2. The light emitting device according to claim 1, comprising:
a first electrode connected to the first structure; and
a second electrode formed on the second main surface, wherein
the metal portion is connected to the second electrode.

3. The light emitting device according to claim 1, wherein the groove is formed in a facing region facing a substantially center of the light emitting region.

4. The light emitting device according to claim 1, wherein the groove is formed in a facing region facing a peripheral edge of the light emitting region.

5. The light emitting device according to claim 1, wherein a size of the groove facing the light emitting region is different between in a first cross-sectional view when being cut in a first direction and in a second cross-sectional view when being cut in a second direction orthogonal to the first direction.

6. The light emitting device according to claim 5, wherein
the light emitting region and the groove face each other in the first cross-sectional view, and
a substantially center of the light emitting region and the groove face each other in the second cross-sectional view.

7. The light emitting device according to claim 5, wherein
light emission intensity distributions of polarized light orthogonal to each other are different.

8. The light emitting device according to claim 1, wherein
the groove has a shape in which a width decreases from the second main surface to the first main surface.

9. The light emitting device according to claim 1, wherein
the metal portion is formed entirely inside the groove.

10. The light emitting device according to claim 1, wherein
the metal portion is a metal layer formed in a layer shape on an inner surface of the groove.

11. The light emitting device according to claim 1, wherein
the groove is formed inside the substrate and across the second multilayer film reflector.

12. The light emitting device according to claim 2, wherein
the metal portion and the second electrode contain the same kind of metal element.

13. The light emitting device according to claim 1, wherein
the metal portion contains at least one metal element selected from the group consisting of gold (Au), aluminum (Al), copper (Cu), titanium (Ti), platinum (Pt), palladium (Pd), germanium (Ge), zinc (Zn), silver (Ag), and tungsten (W).
